(19) United States
(12) Patent Application Publication
(10) Pub. No.: US 2015/0263025 A1
(43) Pub. Date: Sep. 17, 2015

(54) SEMICONDUCTOR MEMORY DEVICE AND METHOD FOR MANUFACTURING SAME

(71) Applicant: Kabushiki Kaisha Toshiba, Minato-ku (JP)

(72) Inventor: Kohei NAKAGAMI, Yokkaichi (JP)

(73) Assignee: Kabushiki Kaisha Toshiba, Minato-ku (JP)

(21) Appl. No.: 14/645,889

(22) Filed: Mar. 12, 2015

(30) Foreign Application Priority Data
Mar. 17, 2014 (JP) 2014-054165

(51) Int. Cl. H01L 27/115; H01L 29/51; H01L 21/768; H01L 23/528; H01L 29/66; H01L 29/792; H01L 23/522

(52) U.S. Cl. CPC H01L 27/11565; H01L 29/7926; H01L 29/513; H01L 23/5226; H01L 23/528; H01L 29/66833; H01L 27/11582; H01L 21/768

(57) ABSTRACT

A semiconductor memory device according to one embodiment includes a substrate, a first stacked body provided on the substrate, a second stacked body provided on the first stacked body, a first semiconductor pillar extending in the first stacked body and the second stacked body, a first memory film provided between the first semiconductor pillar and the first electrode films, a first interconnect, a second interconnect, a first plug and a second plug. The first stacked body includes a plurality of first electrode films and a plurality of first insulating films. The second stacked body includes a plurality of second electrode films and a plurality of second insulating films. The first plug electrically connects the plurality of second electrode films to each other. The second plug electrically connects the plurality of second electrode films to each other.

### CROSS-REFERENCE TO RELATED APPLICATIONS

This application is based upon and claims the benefit of priority from Japanese Patent Application No. 2014-054165, filed on Mar. 17, 2014; the entire contents of which are incorporated herein by reference.

### FIELD

Embodiments described herein relate generally to a semiconductor memory device and a method for manufacturing the same.

### BACKGROUND

In recent years, a stacked type memory device has been proposed to realize higher integration of the memory device. In the stacked type memory device, a stacked body is formed by alternately stacking control gate electrode films and insulating films and forming a selection gate electrode film on the control gate electrode films and the insulating films; a memory hole is made to pierce the stacked body; a charge storage layer is formed on the inner surface of the memory hole; and a semiconductor pillar is formed inside the memory hole. Thereby, memory cells are formed at each intersection between the semiconductor pillar and the control gate electrode films; and a selection transistor is formed at the intersection between the semiconductor pillar and the selection gate electrode film.

### BRIEF DESCRIPTION OF THE DRAWINGS

FIG. 1 to FIG. 4 are plan views showing a semiconductor memory device according to an embodiment;

FIG. 5 and FIG. 6 are cross-sectional views showing the semiconductor memory device according to the embodiment; and

FIGS. 7A and 7B to FIGS. 22A and 22B are cross-sectional views showing a method for manufacturing the semiconductor memory device according to the embodiment.

### DETAILED DESCRIPTION

A semiconductor memory device according to one embodiment includes a substrate, a first stacked body provided on the substrate, a second stacked body provided on the first stacked body, a first semiconductor pillar extending in the first stacked body and the second stacked body, a first memory film provided between the first semiconductor pillar and the first electrode films, a first interconnect, a second interconnect, a first plug and a second plug. The first stacked body includes a plurality of first electrode films and a plurality of first insulating films. Each of the plurality of first electrode films and each of the plurality of first insulating films are stacked alternately. The second stacked body includes a plurality of second electrode films and a plurality of second insulating films. Each of the plurality of second electrode films and each of the plurality of second insulating films are stacked alternately. The first interconnect is provided in a region on the second stacked body including a region directly above the first semiconductor pillar. The first interconnect is connected to the first semiconductor pillar. The second interconnect is provided in a region on the second stacked body where the first interconnect is not provided. The second interconnect is connected to the second electrode film of the uppermost layer. The first plug is provided in a region directly under the second interconnect inside the second stacked body. The first plug electrically connects the plurality of second electrode films to each other. The second plug is provided in a region inside the second stacked body other than the region directly under the second interconnect. The second plug electrically connects the plurality of second electrode films to each other.

An embodiment of the invention will now be described with reference to the drawings.

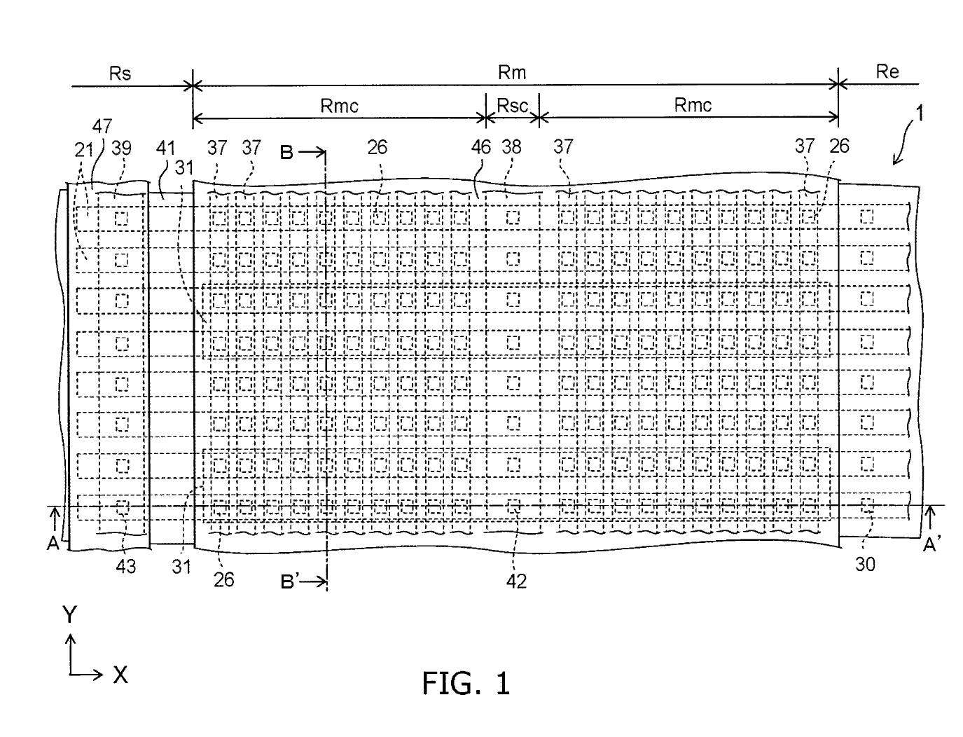

FIG. 1 to FIG. 4 are plan views showing a semiconductor memory device according to the embodiment.

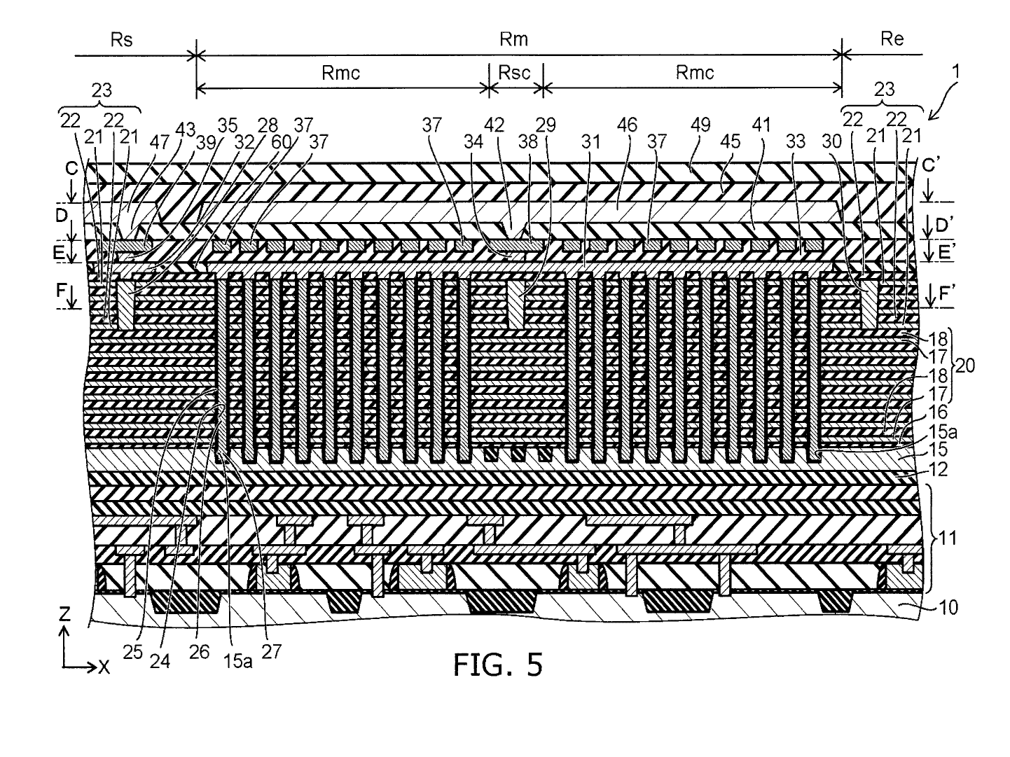

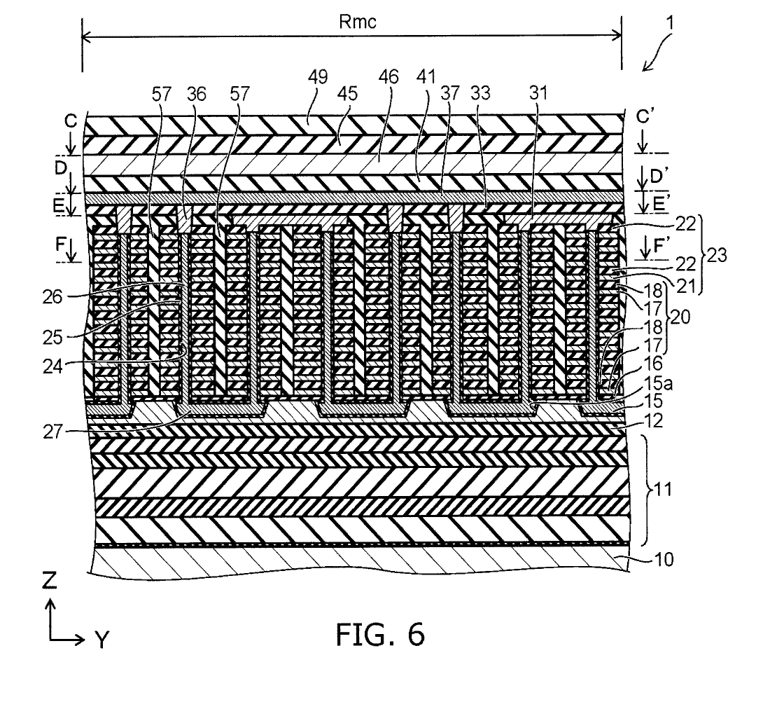

FIG. 5 and FIG. 6 are cross-sectional views showing the semiconductor memory device according to the embodiment.

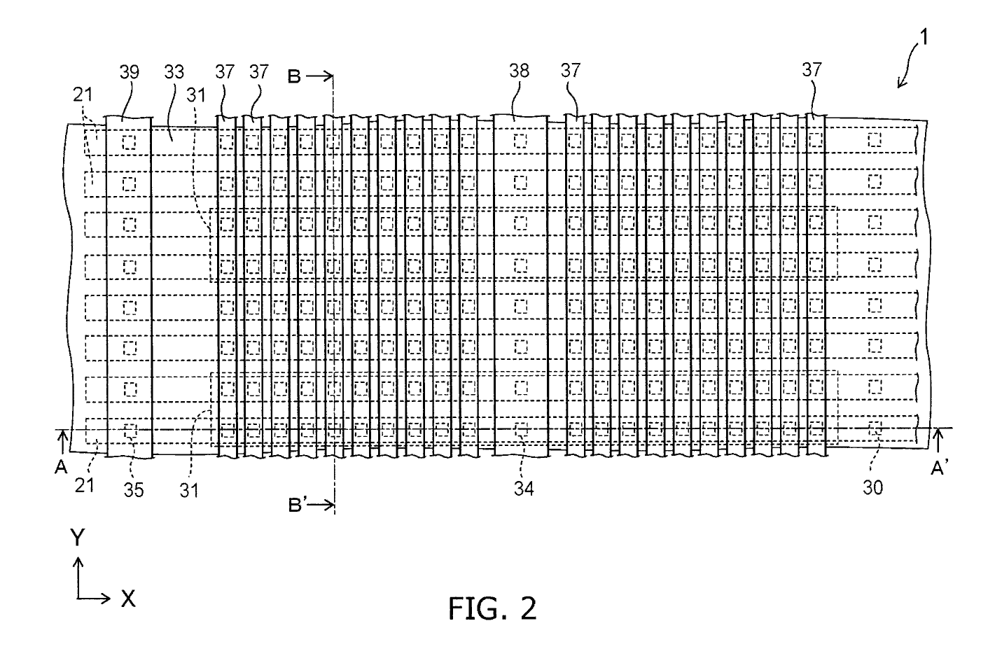

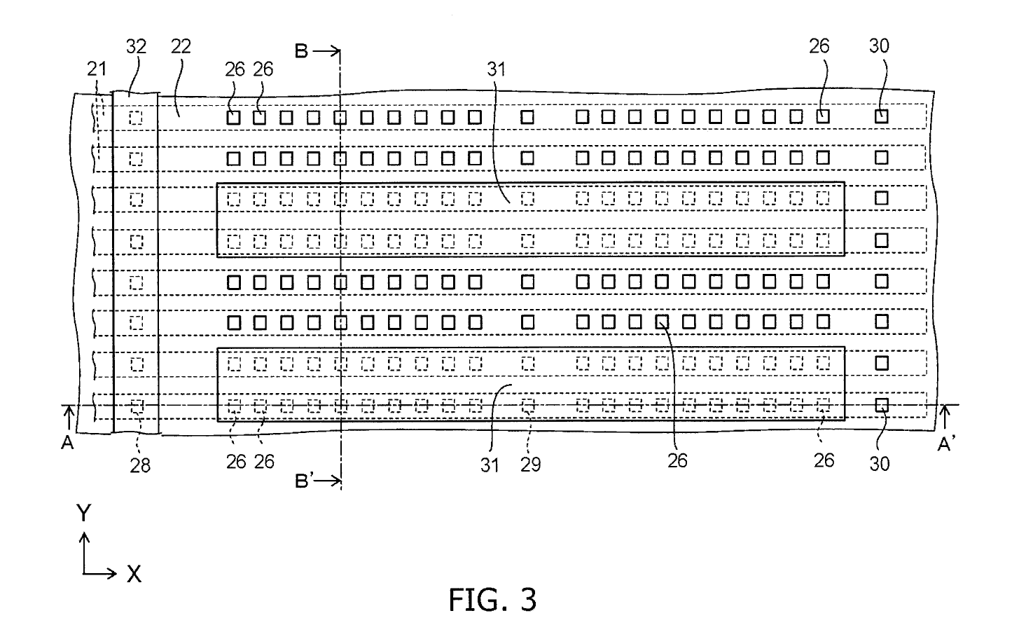

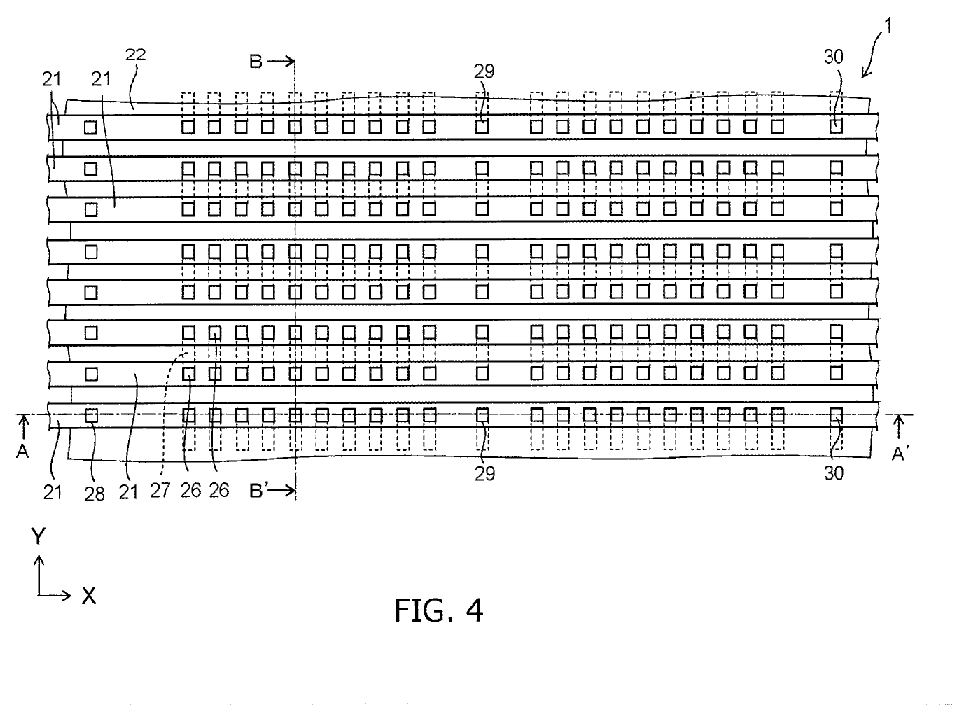

FIG. 5 is a cross-sectional view along line A-A′ shown in FIG. 1 to FIG. 4; and FIG. 6 is a cross-sectional view along line B-B′ shown in FIG. 1 to FIG. 4. FIG. 1 is a plan view as viewed from the position of line C-C′ shown in FIG. 5 and FIG. 6; FIG. 2 is a plan view as viewed from the position of line D-D′ shown in FIG. 5 and FIG. 6; FIG. 3 is a plan view as viewed from the position of line E-E′ shown in FIG. 5 and FIG. 6; and FIG. 4 is a plan view as viewed from the position of line F-F′ shown in FIG. 5 and FIG. 6.

As shown in FIG. 1 to FIG. 6, a silicon substrate 10 is provided in the semiconductor memory device 1 according to the embodiment. In the specification, an XYZ orthogonal coordinate system is employed for convenience of description. Mutually orthogonal directions parallel to the upper surface of the silicon substrate 10 are taken as an X-direction and a Y-direction; and a direction perpendicular to the upper surface of the silicon substrate 10 is taken as a Z-direction. A memory region Rm, a selection gate interconnect region Rs, and a terminal region Re are set in this order along the X-direction on the silicon substrate 10. The selection gate interconnect region Rs is disposed on one side in the X-direction as viewed from the memory region Rm. A memory cell region Rmc and a source interconnect region Rsc are arranged along the X-direction in the memory region Rm. Although an example is illustrated in the embodiment in which one source interconnect region Rsc and two memory cell regions Rmc are set in the memory region Rm, this is not limited thereto; and the source interconnect region Rsc may be set in multiple locations.

A peripheral circuit 11 is provided in the upper layer portion of the silicon substrate 10 and above the upper layer portion. An insulating film 12 is provided on the peripheral circuit 11. A polysilicon film 15 is provided on the insulating film 12. Substantially rectangular parallelepiped recesses 15a are made in the upper surface of the polysilicon film 15 in the memory region Rm. The longitudinal direction of the recesses 15a is the Y-direction. An insulating film 16 is provided on the polysilicon film 15; and a stacked body 20 in which multiple control gate electrode films 17 and multiple inter-electrode insulating films 18 are stacked alternately one film at a time is provided on the insulating film 16. A stacked body 23 in which multiple selection gate electrode films 21 and multiple inter-electrode insulating films 22 are stacked alternately one film at a time is provided on the stacked body 20.

The control gate electrode films 17 and the selection gate electrode films 21 are formed of conductive materials, e.g., polysilicon; and the inter-electrode insulating films 18 and 22 are formed of insulating materials, e.g., silicon oxide. The film thickness of the control gate electrode films 17 and the film thickness of the selection gate electrode films 21 are substantially equal to each other. Although the number of control gate electrode films 17 in the Z-direction is, for example, eight and the number of selection gate electrode films 21 in the Z-direction is, for example, four, the numbers are not limited thereto. The control gate electrode films 17 and the selection gate electrode films 21 are separated in the Y-direction by an insulating member 57; and each separated portion extends in the X-direction.

In the memory cell region Rmc, memory holes 24 that extend in the Z-direction are multiply made in the stacked body and the stacked body 23. When viewed from the Z-direction, for example, the memory holes 24 are arranged in a matrix configuration along the X-direction and the Y-direction. The memory holes 24 pierce all of the selection gate electrode films 21 and control gate electrode films 17 arranged along the Z-direction to reach two longitudinal-direction (Y-direction) end portions of the recess 15a of the polysilicon film 15 and communicate with the recess 15a. A memory film 25 in which a blocking layer (not shown), a charge storage layer (not shown), and a tunneling layer (not shown) are stacked in this order is formed on the inner surfaces of the memory holes 24 and the recess 15a. The memory film 25 is provided at least between a silicon pillar 26 and the control gate electrode films 17 and is a film that can transfer charge between the memory film 25 and the silicon pillar 26 and store the charge. The silicon pillars 26 are provided inside the memory holes 24; and a connection member 27 is provided inside the recess 15a. The connection member 27 is a semiconductor member that connects the lower end portions of two silicon pillars 26 to each other and is formed of, for example, polysilicon as one body with the two silicon pillars 26. The silicon pillars 26 are not provided in the source interconnect region Rsc.

Plugs 28 to 30 are provided inside the stacked body 23, extend in the Z-direction, and electrically connect the selection gate electrode films 21 to each other. The plugs 28 are provided in the selection gate interconnect region Rs; the plugs 29 are provided in the source interconnect region Rsc; and the plugs 30 are provided in the terminal region Re. Accordingly, the plugs 30 are disposed at positions so that the silicon pillars 26 are interposed between the plugs 30 and the plugs 28.

Multiple source lines 31 and an intermediate interconnect 32 are provided in the same layer on the stacked body 23. The source lines 31 are disposed in the memory region Rm and extend in the X-direction. The width of each of the source lines corresponds to two columns of the silicon pillars 26 extending in the X-direction; and the source lines 31 are provided in the regions directly above every other set of two columns of the silicon pillars 26. The lower surfaces of the source lines 31 are connected to the upper ends of the silicon pillars 26. The intermediate interconnect 32 is disposed in the selection gate interconnect region Rs and extends in the Y-direction to pass through the region directly above the plugs 28. The lower surface of the intermediate interconnect 32 is connected to the upper ends of the plugs 28.

An inter-layer insulating film 33 is provided on the source lines 31 and the intermediate interconnect 32. Plugs 34 to 36 are provided inside the lower portion of the inter-layer insulating film 33. The plugs 34 are provided in the regions directly above the plugs 29 in the source interconnect region Rsc; and the lower ends of the plugs 34 are connected to the upper surfaces of the source lines 31. The plugs 35 are provided in the regions directly above the plugs 28 in the selection gate interconnect region Rs; and the lower ends of the plugs 35 are connected to the upper surface of the intermediate interconnect 32. The plugs 36 are provided in the memory cell region Rmc; and the lower ends of the plugs 36 are connected to the upper ends of the silicon pillars 26 that are not connected to the source lines 31.

Multiple bit lines 37, an intermediate interconnect 38, and an intermediate interconnect 39 are provided in the same layer inside the upper portion of the inter-layer insulating film 33. The bit line 37 extends in the Y-direction and is disposed in the region directly above a column of the silicon pillars 26 extending in the Y-direction in the memory cell region Rmc. The width of each of the bit lines 37 corresponds to one column of the silicon pillars 26 arranged in the Y-direction. One of the two silicon pillars 26 connected to the same connection member 27 is connected to the source line 31; and the other silicon pillar 26 is connected to the bit line 37 via the plug 36. The intermediate interconnect 38 is disposed in the source interconnect region Rsc and extends in the Y-direction. The lower surface of the intermediate interconnect 38 is connected to the upper ends of the plugs 34. The intermediate interconnect 39 is disposed in the selection gate interconnect region Rs and extends in the Y-direction. The lower surface of the intermediate interconnect 39 is connected to the upper ends of the plugs 35.

An inter-layer insulating film 41 is provided on the inter-layer insulating film 33. Plugs 42 and 43 are provided inside the inter-layer insulating film 41. The plugs 42 are disposed in the regions directly above the plugs 34 in the source interconnect region Rsc; and the lower ends of the plugs 42 are connected to the upper surface of the intermediate interconnect 38. The plugs 43 are disposed in the regions directly above the plugs 35 in the selection gate interconnect region Rs; and the lower ends of the plugs 43 are connected to the upper surface of the intermediate interconnect 39.

An inter-layer insulating film 45 is provided on the inter-layer insulating film 41. A source upper layer interconnect 46 and a selection gate upper layer interconnect 47 are provided in the same layer inside the lower portion of the inter-layer insulating film 45. The source upper layer interconnect 46 extends in the Y-direction in the memory region Rm; and the width of the source upper layer interconnect 46 is about the same as the width of the memory region Rm. The lower surface of the source upper layer interconnect 46 is connected to the upper ends of the plugs 42. The source upper layer interconnect 46 is not provided in the selection gate interconnect region Rs. The selection gate upper layer interconnect 47 extends in the Y-direction in the selection gate interconnect region Rs. The lower surface of the selection gate upper layer interconnect 47 is connected to the upper ends of the plugs 43. An inter-layer insulating film 49 is provided on the inter-layer insulating film 45.

A method for manufacturing the semiconductor memory device according to the embodiment will now be described.

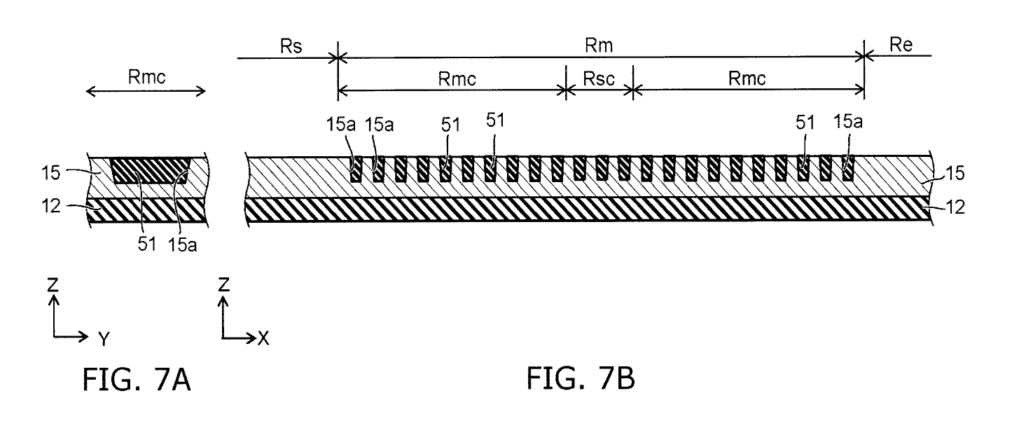

FIGS. 7A and 7B to FIGS. 22A and 22B are cross-sectional views showing the method for manufacturing the semiconductor memory device according to the embodiment. The silicon substrate 10 and the peripheral circuit 11 are not shown in these drawings.

First, the silicon substrate 10 is prepared as shown in FIG. 5 and FIG. 6. The selection gate interconnect region Rs, the memory region Rm, and the terminal region Re are set in the silicon substrate 10 and are arranged in this order along the X-direction. The memory cell region Rmc and the source interconnect region Rsc are set in the memory region Rm and are arranged along the X-direction. Then, the peripheral circuit 11 is formed on the silicon substrate 10; and the insulating film 12 and the polysilicon film 15 are formed in this order on the peripheral circuit 11.

Then, as shown in FIGS. 7A and 7B, the substantially rectangular recess 15a is multiply made in a matrix configuration having the Y-direction as the longitudinal direction in the upper surface of the polysilicon film 15 in the memory region Rm. Then, for example, a sacrificial member 51 that is made of silicon nitride (SiN) is filled into the recesses 15a by depositing the sacrificial member 51 over the entirety and performing planarization.

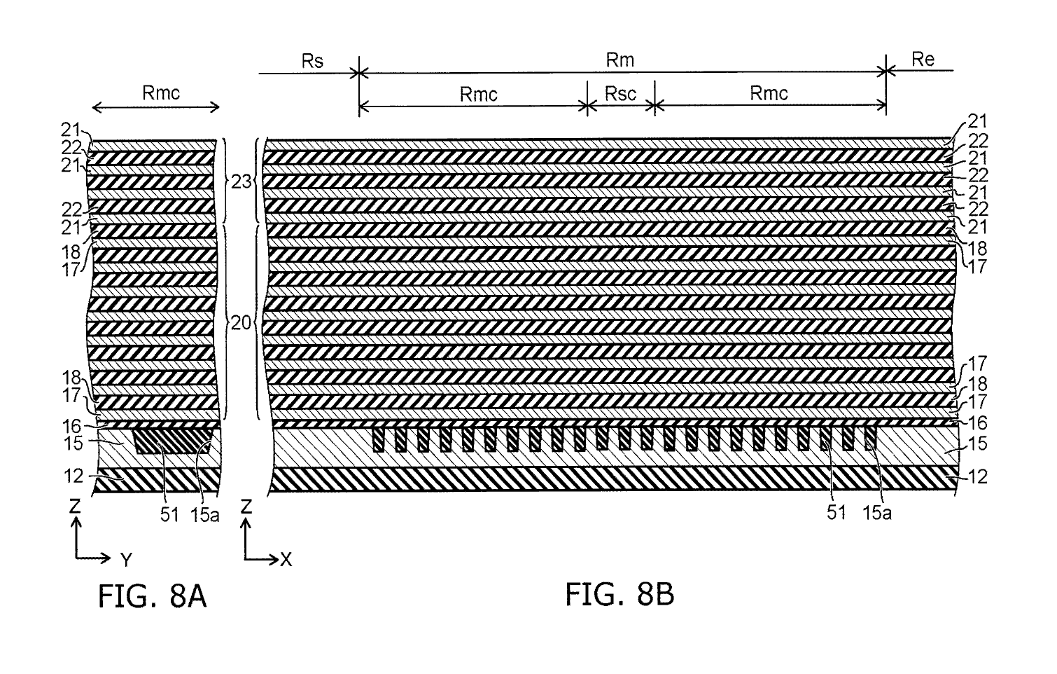

Continuing as shown in FIGS. 8A and 8B, for example, the insulating film 16 is formed on the entire surface by depositing silicon nitride. Then, the stacked body 20 is formed by alternately forming the control gate electrode films 17 made of polysilicon and the inter-electrode insulating films 18 made of silicon oxide. Then, the stacked body 23 is formed by alternately forming the selection gate electrode films 21 made of polysilicon and the inter-electrode insulating films 22 made of silicon oxide.

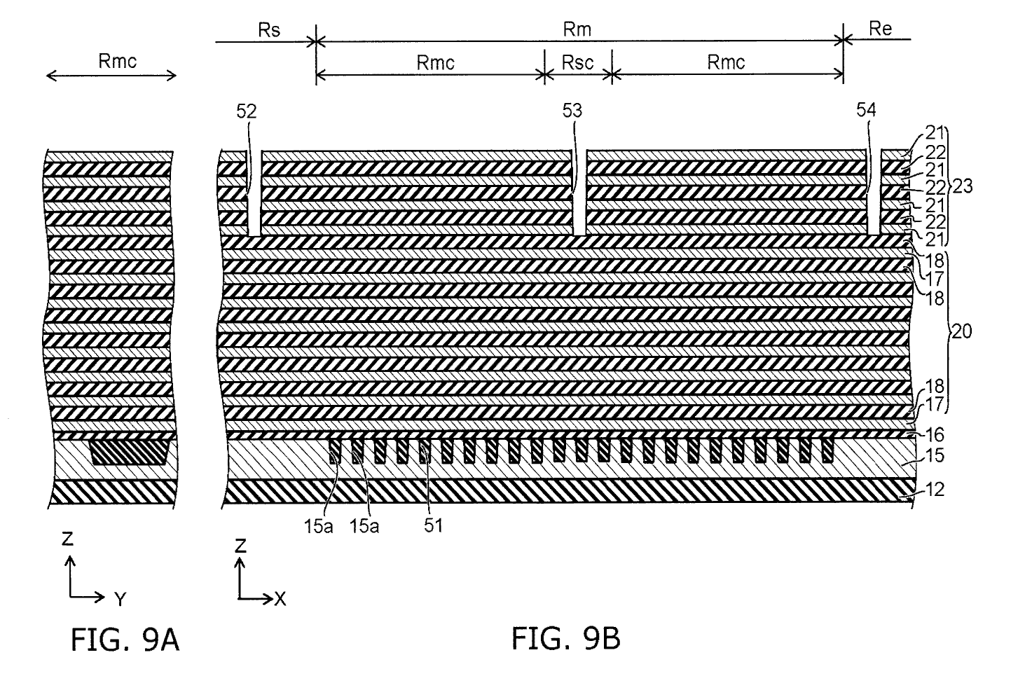

Then, as shown in FIGS. 9A and 9B, pluralities of each of plug holes 52 to 54 are made by, for example, RIE (reactive ion etching) to pierce the stacked body 23 in the Z-direction but not to enter the stacked body 20. The plug holes 52 are made in the selection gate interconnect region Rs; the plug holes 53 are made in the source interconnect region Rsc in the memory region Rm; and the plug holes 54 are made in the terminal region Re. The plug holes 52 are arranged in one column along the Y-direction; the plug holes 53 are arranged in one column along the Y-direction; and the plug holes 54 are arranged in one column along the Y-direction.

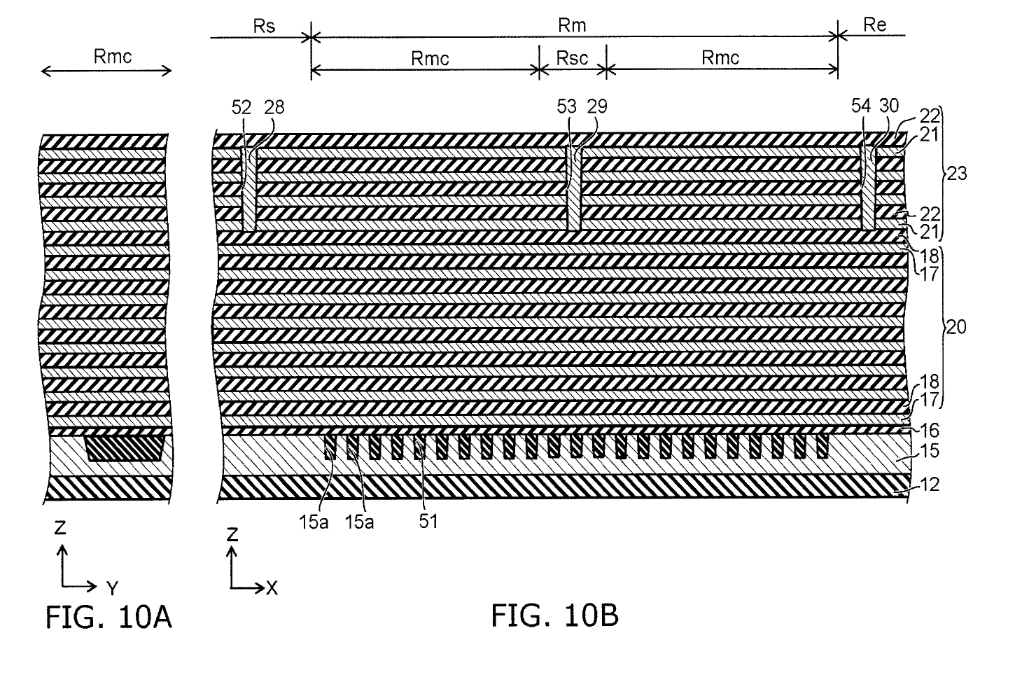

Continuing as shown in FIGS. 10A and 10B, a conductive material, e.g., polysilicon, is filled into the plug holes 52 to 54. Thereby, the plugs 28 are formed inside the plug holes 52; the plugs 29 are formed inside the plug holes 53; and the plugs 30 are formed inside the plug holes 54. Then, one more layer of the inter-electrode insulating film 22 is formed by depositing silicon oxide.

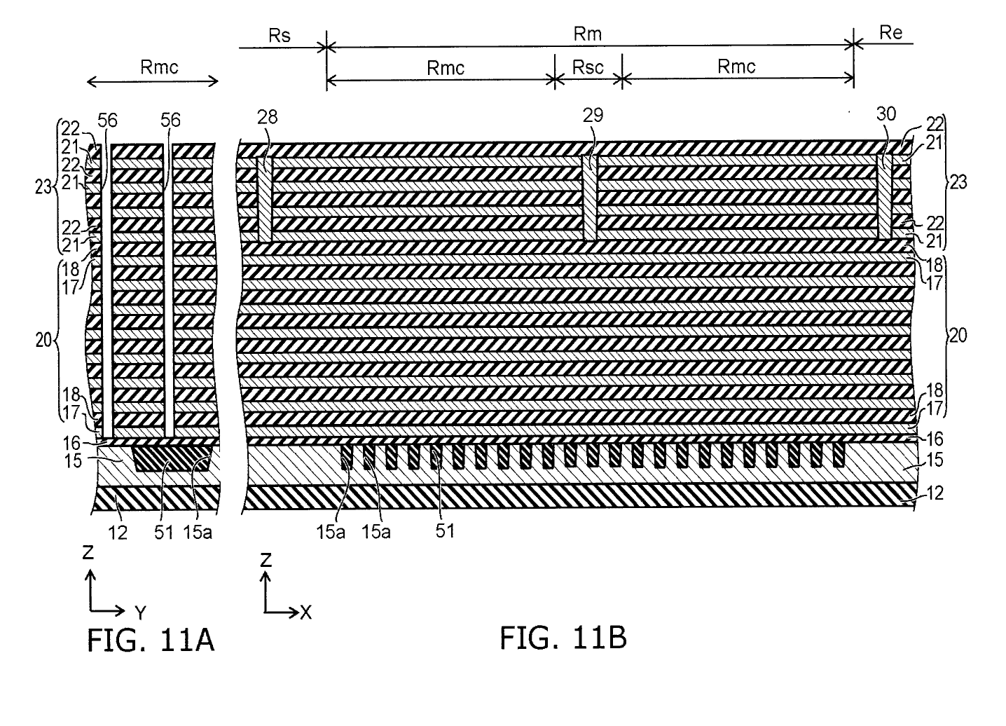

Then, as shown in FIGS. 11A and 11B, trenches 56 are made by lithography and RIE in the stacked bodies 20 and 23 to extend in the X-direction and pierce the stacked bodies 20 and 23. However, the trenches 56 do not pierce the insulating film 16. Thereby, each of the control gate electrode films 17 and each of the selection gate electrode films 21 are divided into multiple portions having line configurations extending in the X-direction. Every other one of the trenches 56 is made in the region directly above the Y-direction central portion of the recess 15a or in the region directly above the region between the recesses 15a.

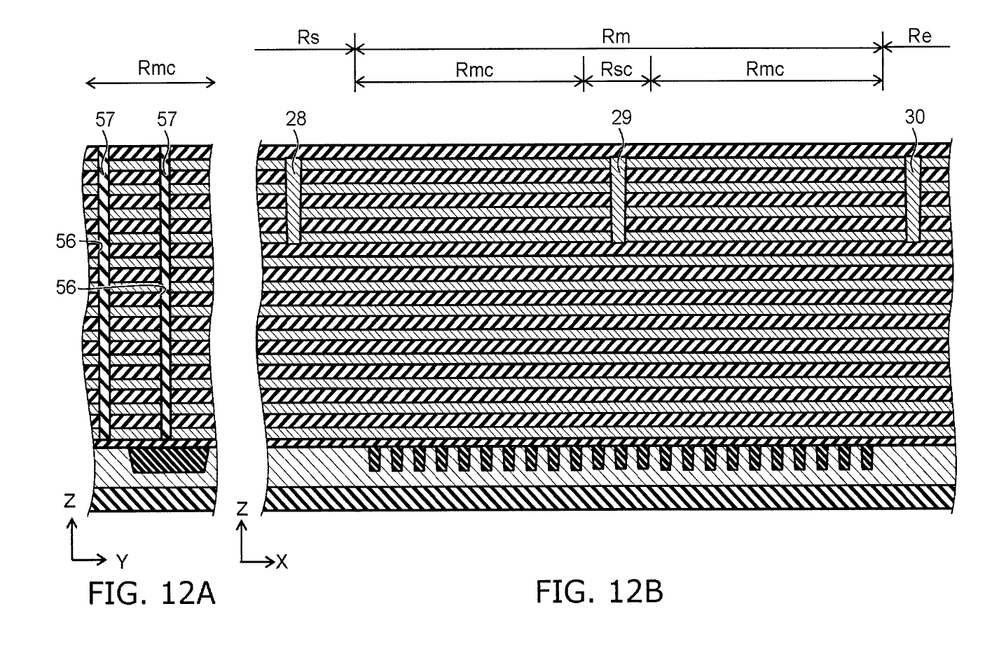

Continuing as shown in FIGS. 12A and 12B, the insulating members 57 are formed by filling an insulating material, e.g., silicon oxide, into the trenches 56.

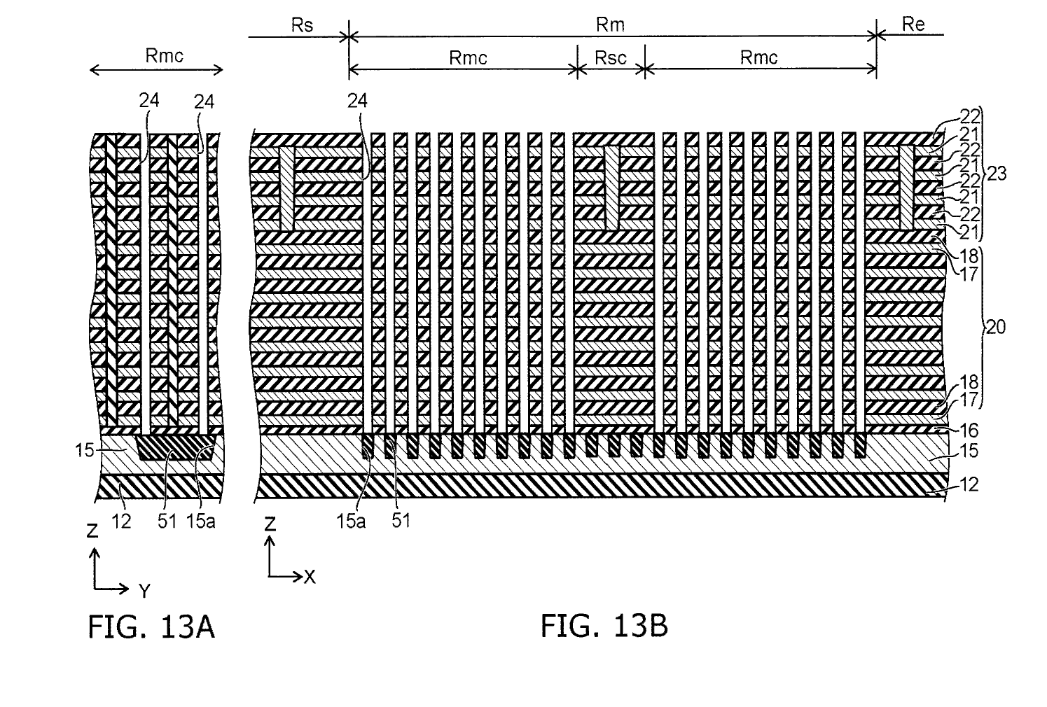

Then, as shown in FIGS. 13A and 13B, the memory holes 24 that extend in the Z-direction are made in the stacked bodies 20 and 23 in the memory cell region Rmc by lithography and RIE. When viewed from the Z-direction, the memory holes 24 are made in a matrix configuration to reach the two Y-direction end portions of the recess 15a.

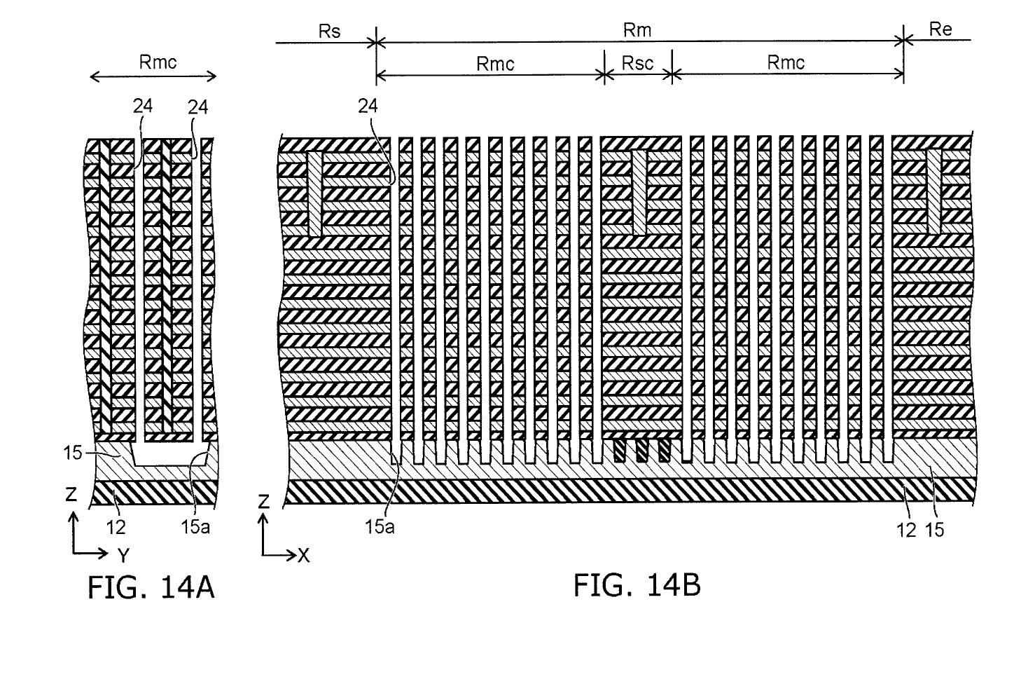

Continuing as shown in FIGS. 14A and 14B, etching of the sacrificial member 51 is performed via the memory holes 24. For example, wet etching is performed using a hot phosphoric acid solution. Thereby, the sacrificial member 51 is removed; and a U-shaped hole is made by causing two memory holes 24 to communicate with one recess 15a.

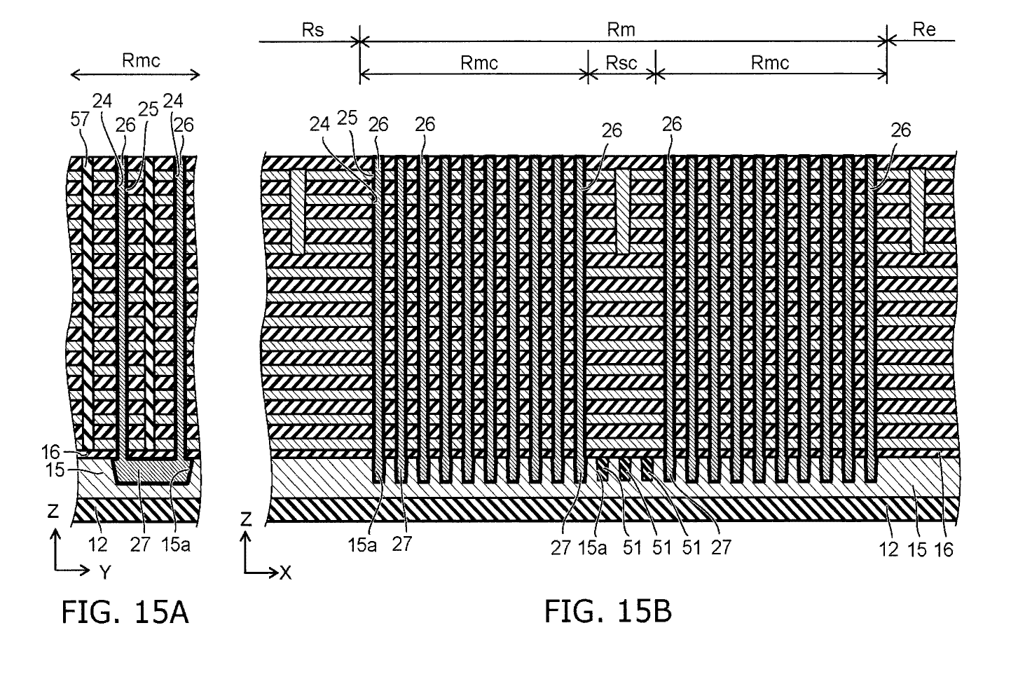

Then, as shown in FIGS. 15A and 15B, the memory film 25 is formed on the inner surface of the U-shaped hole by forming a blocking layer (not shown), a charge storage layer (not shown), and a tunneling layer (not shown) in this order. The memory film 25 is, for example, an ONO film in which a silicon oxide layer/silicon nitride layer/silicon oxide layer are stacked in this order. Then, polysilicon is filled into the memory holes 24 on the surface of the memory film 25. Thereby, the silicon pillars 26 that are used as the channels of the memory cells are formed inside the memory holes 24; and the connection member 27 is formed inside the recess 15a. Then, the polysilicon film and the memory film 25 that are formed on the upper surface of the stacked body 23 are removed by RIE.

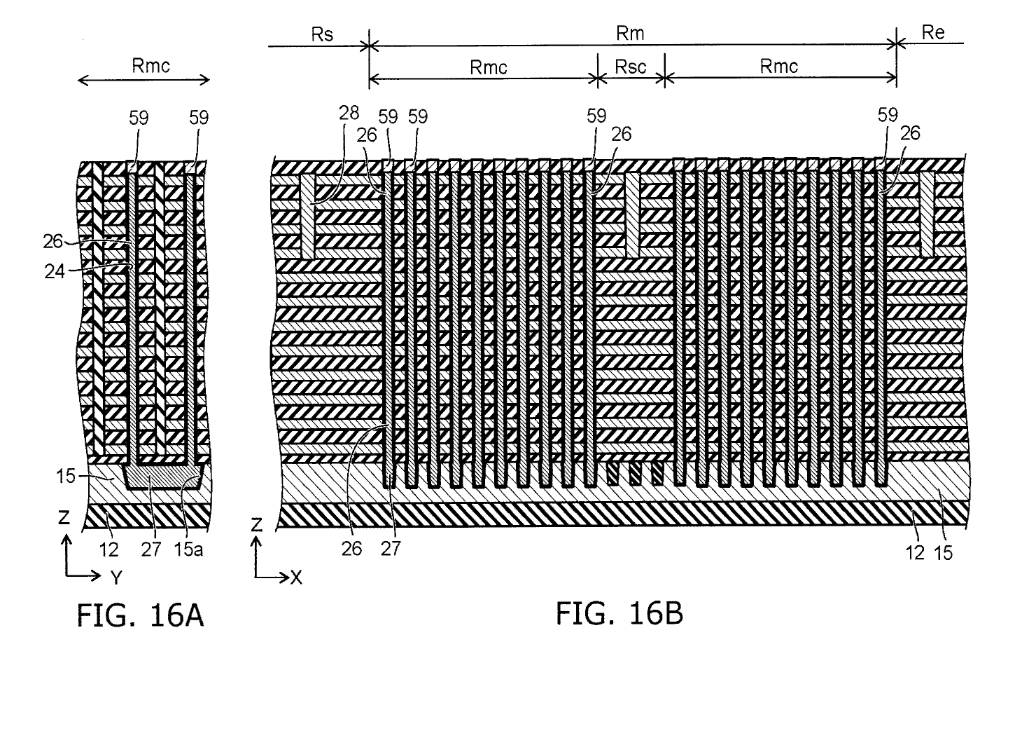

Continuing as shown in FIGS. 16A and 16B, the upper portions of the silicon pillars 26 are caused to recede by, for example, RIE. Then, polysilicon is filled into the portions where the upper portions of the silicon pillars 26 were caused to recede; and the upper surface is planarized. Thereby, contact units 59 for a metal member formed in a subsequent process are formed inside the upper portions of the memory holes 24. A memory string in which multiple memory cells are connected in series is formed inside the U-shaped hole.

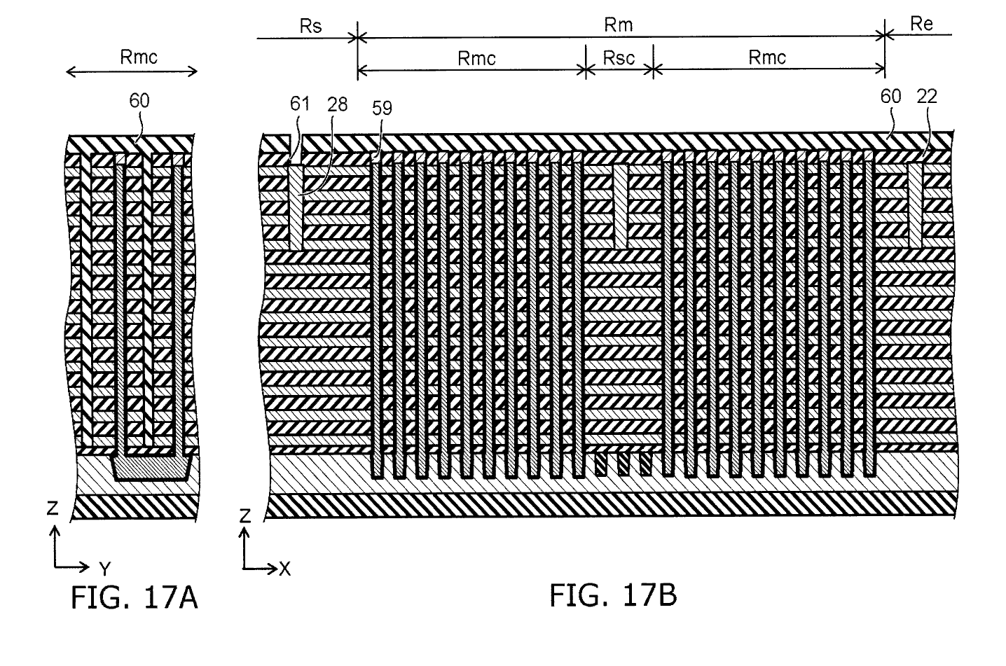

Then, as shown in FIGS. 17A and 17B, an inter-layer insulating film 60 is formed by, for example, depositing silicon oxide by plasma CVD (chemical vapor deposition). Then, for example, plug holes 61 are made in the inter-layer insulating film 60 and the inter-electrode insulating film 22 one layer under the inter-layer insulating film 60 in the regions directly above the plugs 28 by RIE.

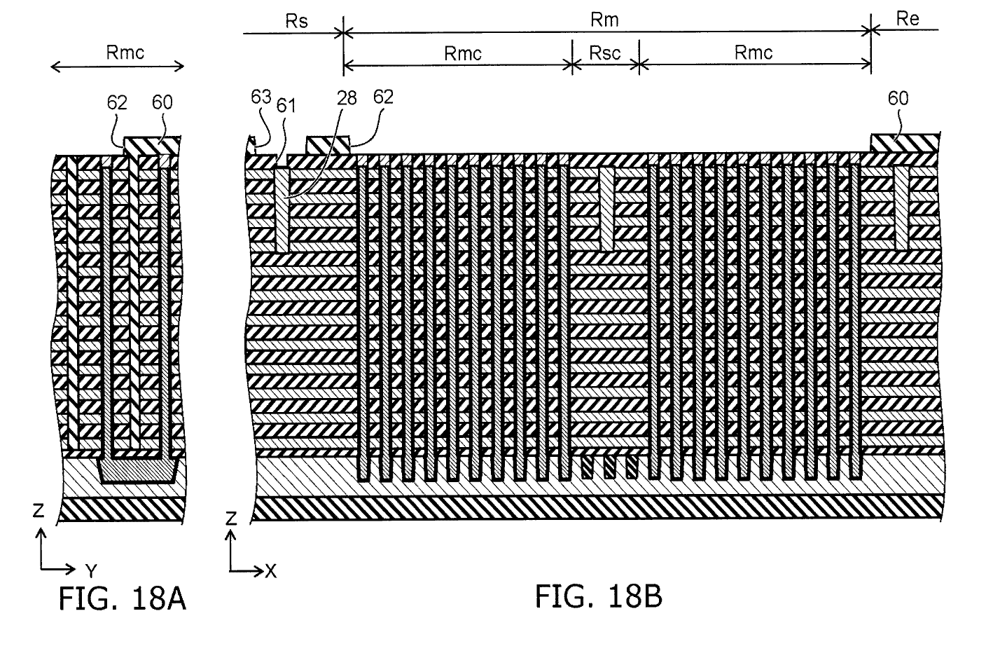

Continuing as shown in FIGS. 18A and 18B, an interconnect trench 62 is made in the region of the inter-layer insulating film 60 where the source line 31 is to be formed; and an interconnect trench 63 is made in the region of the inter-layer insulating film 60 where the intermediate interconnect 32 is to be formed.

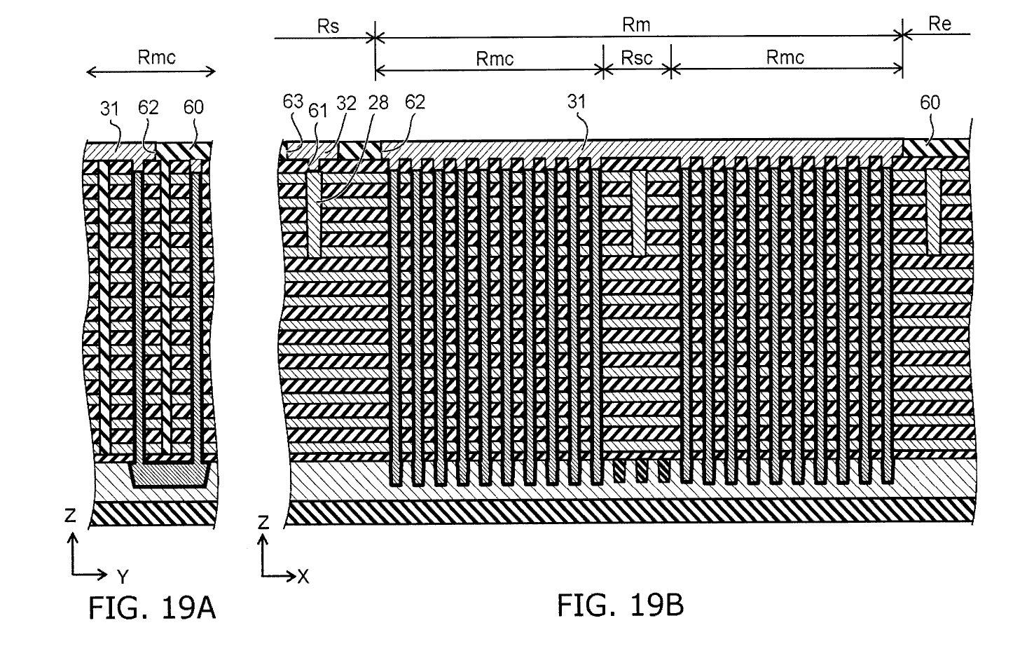

Then, as shown in FIGS. 19A and 19B, a conductive film, e.g., a (Ti/TiN/W) stacked film in which a titanium layer/titanium nitride layer/tungsten layer are stacked in this order is formed; and the portion that is deposited on the inter-layer insulating film 60 is removed by CMP (chemical mechanical polishing). Thus, by a so-called dual damascene process, plugs are formed inside the plug holes 61; and the intermediate interconnect 32 is formed inside the interconnect trench 63. Also, the source line 31 is formed inside the interconnect trench 62. Thereby, one of the two silicon pillars 26 connected to each of the connection members 27 is connected to one source line 31.

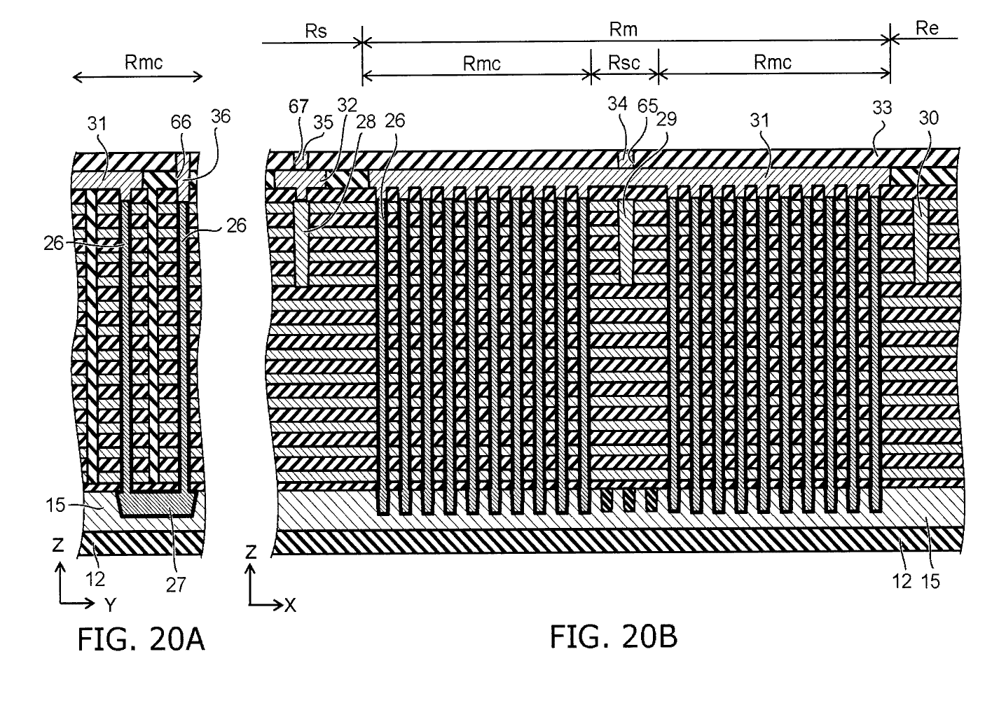

Then, as shown in FIGS. 20A and 20B, the lower layer portion of the inter-layer insulating film 33 is formed. Then, by lithography and RIE, plug holes 65 are made in the regions directly above the plugs 29 in the lower layer portion of the inter-layer insulating film 33; plug holes 66 are made in the regions directly above the silicon pillars 26 not connected to the source line 31 in the lower layer portion of the inter-layer insulating film 33; and plug holes 67 are made in the regions directly above the plugs 28 in the lower layer portion of the inter-layer insulating film 33. Then, a conductive film, e.g., a (Ti/TiN/W) stacked film is formed; and the portion that is deposited on the lower layer portion of the inter-layer insulating film 33 is removed by CMP. Thereby, the plugs 34 are formed inside the plug holes 65; the plugs 36 are formed inside the plug holes 66; and the plugs 35 are formed inside the plug holes 67.

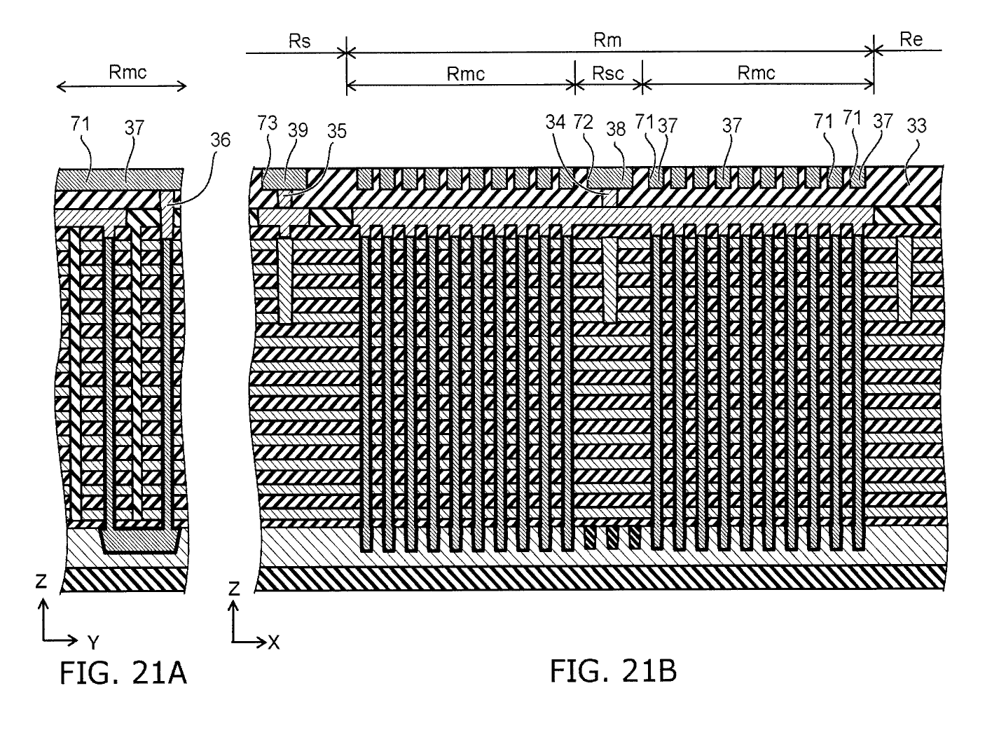

Continuing as shown in FIGS. 21A and 21B, the upper layer portion of the inter-layer insulating film 33 is formed. Then, interconnect trenches 71 to 73 are made by lithography and RIE respectively in the regions of the upper layer portion of the inter-layer insulating film 33 where the bit lines 37 are to be formed, the region of the upper layer portion of the inter-layer insulating film 33 where the intermediate interconnect 38 is to be formed, and the region of the upper layer portion of the inter-layer insulating film 33 where the intermediate interconnect 39 is to be formed. Then, a conductive film, e.g., a (Ta/TaN/Cu) stacked film in which a tantalum layer/tantalum nitride layer/copper layer are stacked in this order is formed; and the portion that is deposited on the inter-layer insulating film 33 is removed by CMP. Thereby, the bit lines 37 are formed inside the interconnect trenches 71; the intermediate interconnect 38 is formed inside the interconnect trench 72; and the intermediate interconnect 39 is formed inside the interconnect trench 73.

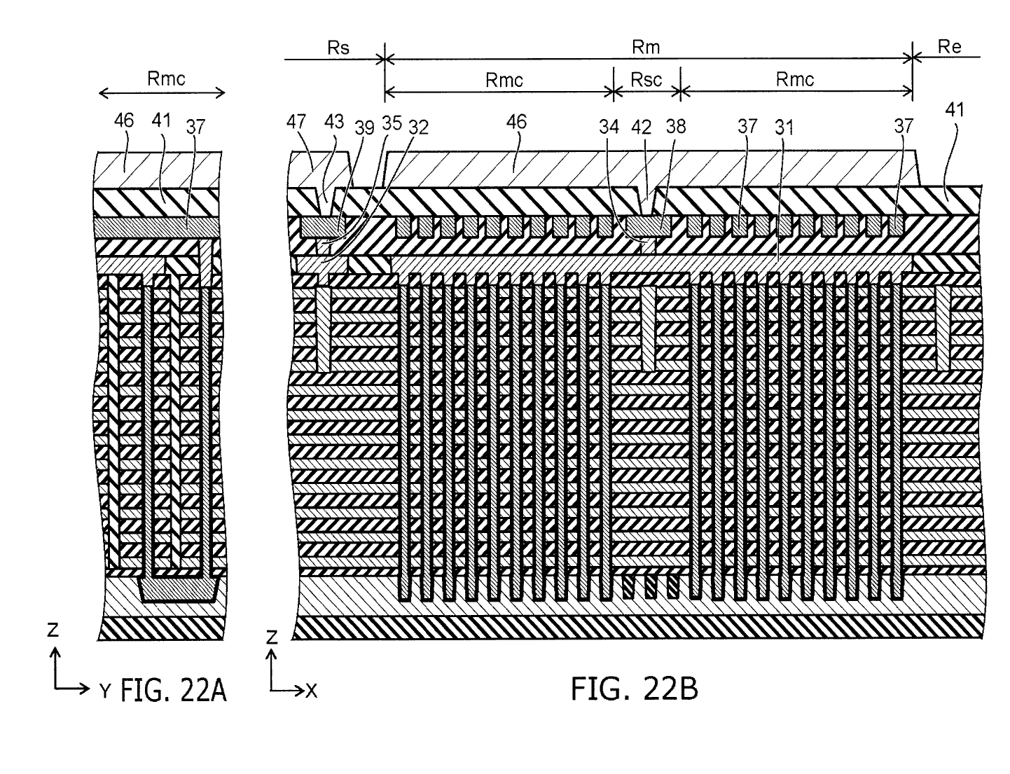

Then, as shown in FIGS. 22A and 22B, the inter-layer insulating film 41 is formed; and plug holes are made in the regions directly above the plugs 34 and the regions directly above the plugs 35. Then, a conductive film, e.g., a (Ti/TiN/AlCu) stacked film in which a titanium layer/titanium nitride layer/copper-aluminum alloy layer are stacked in this order is formed; and the conductive film is patterned by lithography and RIE. Thereby, the plugs 42 and the plugs 43 are formed inside the inter-layer insulating film 41, and the source upper layer interconnect 46 and the selection gate upper layer interconnect 47 are formed on the inter-layer insulating film 41. The source upper layer interconnect 46 is formed in a region that includes the regions directly above the plugs 29 but does not include the regions directly above the plugs 28. The selection gate upper layer interconnect 47 is formed in a region that includes the regions directly above the plugs 28 but does not include the regions directly above the plugs 29. Also, bonding pads (not shown) are formed at this time.

Continuing as shown in FIG. 5 and FIG. 6, to protect the device, the inter-layer insulating film 45 that is made of silicon oxide is formed; and the inter-layer insulating film 49 that is made of silicon nitride is formed. Then, openings at the portions of the bonding pads are made in the inter-layer insulating films 45 and 49. Thus, the semiconductor memory device 1 according to the embodiment is manufactured.

Effects of the embodiment will now be described.

In the semiconductor memory device according to the embodiment, multiple selection gate electrode films 21, e.g., four films, are stacked along the Z-direction, connected to each other by the plugs 28 to 30, and used as the gate electrode of the selection transistor. Thereby, the thickness of each of the selection gate electrode films 21 can be set to be about the same as the thicknesses of the control gate electrode films 17 while ensuring the necessary length for the gate length of the selection transistor. As a result, it is easy to make the memory holes 24.

In the embodiment, the plugs 28, 29, and 30 are provided as plugs for current division that connect the selection gate electrode films 21 to each other. Thereby, it is possible to reduce the difference between the current propagation velocities of each layer of the selection gate electrode films 21. As a result, the delay of the circuit operation can be reduced even in the case where the selection gate electrode films 21 are formed to be thin.

The effects will now be described in more detail.

The selection gate electrode film 21 of the lowermost layer of the multiple selection gate electrode films 21 is strongly affected by the electric field generated by the operation of the control gate electrode film 17 disposed under the selection gate electrode film 21 of the lowermost layer. Therefore, if the selection gate electrode films 21 are connected to each other by only the plug 28 provided directly under the selection gate upper layer interconnect 47, compared to the other selection gate electrode films 21, the propagation velocity of the current would be slower and more time would be necessary for charging for the selection gate electrode film 21 of the lowermost layer. Moreover, the operation of the entire semiconductor memory device 1 undesirably becomes slower if the operation timing is designed using the selection gate electrode film 21 of the lowermost layer as the reference.

Therefore, in the embodiment, the plug 29 is provided in the middle portion in the longitudinal direction of the selection gate electrode films 21 to connect the selection gate electrode film 21 of the lowermost layer to the selection gate electrode films 21 of the higher layers. Thereby, the delay of the current in the selection gate electrode film 21 of the lowermost layer is suppressed. As a result, the operation speed of the entire semiconductor memory device 1 can be increased. Also, by providing the plug 30 at the end portion of the selection gate electrode films 21, the operation speed can be increased reliably for the selection gate transistors disposed at the positions most distal to the selection gate upper layer interconnect 47.

In the embodiment, the plugs 29 are provided in the regions directly under the plugs 34. The plugs 34 are plugs for connecting the source upper layer interconnect 46 to the source line 31 and are necessary regardless of the selection gate electrode films 21. Also, because the bit lines 37 cannot be disposed in the regions directly above the plugs 34, the silicon pillars 26 cannot be provided in the regions directly under the plugs 34; and this region becomes dead space. In the embodiment, because the plugs 28 are disposed by effectively utilizing the dead space, the space for disposing the silicon pillars 26 is not reduced due to the plugs 28 being provided. As a result, the plugs 28 can be provided and the operation speed can be increased without reducing the integration of the memory cells of the semiconductor memory device 1.

According to the embodiment described above, a semiconductor memory device and a method for manufacturing the semiconductor memory device having a high operation speed can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device, comprising:
a substrate;
a first stacked body provided on the substrate, the first stacked body including a plurality of first electrode films and a plurality of first insulating films, each of the plurality of first electrode films and each of the plurality of first insulating films being stacked alternately;
a second stacked body provided on the first stacked body, the second stacked body including a plurality of second electrode films and a plurality of second insulating films, each of the plurality of second electrode films and each of the plurality of second insulating films being stacked alternately;
a first semiconductor pillar extending in the first stacked body and the second stacked body;
a first memory film provided between the first semiconductor pillar and the first electrode films;
a first interconnect provided in a region on the second stacked body including a region directly above the first semiconductor pillar, the first interconnect being connected to the first semiconductor pillar;
a second interconnect provided in a region on the second stacked body where the first interconnect is not provided, the second interconnect being connected to the second electrode film of the uppermost layer;
a first plug electrically connecting the plurality of second electrode films to each other; and
a second plug electrically connecting the plurality of second electrode films to each other.

2. The device according to claim 1, wherein
the first plug is provided in a region directly under the second interconnect inside the second stacked body, and
the second plug is provided in a region inside the second stacked body other than the region directly under the second interconnect.

3. The device according to claim 1, further comprising:
a second semiconductor pillar extending in the first stacked body and the second stacked body;
a second memory film provided between the second semiconductor pillar and the first electrode films;
a connection member connecting a lower end portion of the first semiconductor pillar to a lower end portion of the second semiconductor pillar;
a third interconnect provided on the second stacked body and connected to the second semiconductor pillar;
a fourth interconnect provided on the first interconnect; and
a third plug electrically connecting the fourth interconnect to the third interconnect,
the second plug being disposed in a region directly under the third plug.

4. The device according to claim 3, further comprising a fourth plug provided in a position inside the second stacked body having the first semiconductor pillar interposed between the first plug and the fourth plug, the fourth plug electrically connecting the plurality of second electrode films to each other.

5. The device according to claim 3, wherein the second interconnect and the fourth interconnect are disposed in the same layer.

6. The device according to claim 1, wherein the second plug is disposed at a position having the first semiconductor pillar interposed between the first plug and the second plug.

7. The device according to claim 1, further comprising a first intermediate interconnect connected between the second interconnect and the first plug.

8. The device according to claim 7, further comprising:
a second semiconductor pillar extending in the first stacked body and the second stacked body;
a second memory film provided between the second semiconductor pillar and the first electrode films;
a connection member connecting a lower end portion of the first semiconductor pillar to a lower end portion of the second semiconductor pillar;
a third interconnect provided on the second stacked body and connected to the second semiconductor pillar;
a fourth interconnect provided on the first interconnect; and
a third plug electrically connecting the fourth interconnect to the third interconnect,
the second plug being disposed in a region directly under the third plug,
the first intermediate interconnect being disposed in the same layer as the second interconnect.

9. The device according to claim 8, further comprising:
a second intermediate interconnect connected between the second interconnect and the first intermediate interconnect and disposed in the same layer as the first interconnect; and
a third intermediate interconnect connected between the third interconnect and the fourth interconnect and disposed in the same layer as the first interconnect.

10. The device according to claim 1, wherein
the first semiconductor pillar extends in a stacking direction of the first electrode films and the first insulating films,
the first electrode films and the second electrode films extend in a first direction intersecting the stacking direction; and
the first interconnect and the second interconnect extend in a second direction intersecting the stacking direction and the first direction.

11. The device according to claim 3, wherein
the first semiconductor pillar and the second semiconductor pillar extend in a stacking direction of the first electrode films and the first insulating films,
the first electrode films, the second electrode films, and the third interconnect extend in a first direction intersecting the stacking direction; and
the first interconnect, the second interconnect, the fourth interconnect, and the connection member extend in a second direction intersecting the stacking direction and the first direction.

12. The device according to claim 9, wherein
the first semiconductor pillar and the second semiconductor pillar extend in a stacking direction of the first electrode films and the first insulating films,
the first electrode films, the second electrode films, and the third interconnect extend in a first direction intersecting the stacking direction, and
the first interconnect, the second interconnect, the fourth interconnect, the connection member, the first intermediate interconnect, the second intermediate interconnect, and the third intermediate interconnect extend in a second direction intersecting the stacking direction and the first direction.

13. The device according to claim 1, wherein a film thickness of the second electrode films is equal to a film thickness of the first electrode films.

14. A method for manufacturing a semiconductor memory device, comprising:
forming a first stacked body on a substrate by alternately stacking each of a plurality of first electrode films and each of a plurality of first insulating films;
forming a second stacked body on the first stacked body by alternately stacking each of a plurality of second electrode films and each of a plurality of second insulating films;
forming a first plug and a second plug inside the second stacked body to electrically connect the plurality of second electrode films to each other;
making a hole to pierce the first stacked body and the second stacked body in a region where the first plug and the second plug are not provided;
forming a memory film on an inner surface of the hole;
forming a semiconductor pillar inside the hole;
forming a first interconnect being connected to the semiconductor pillar; and
forming a second interconnect being connected to the second electrode film of the uppermost layer.

15. The method according to claim 14, wherein
the first interconnect is formed in a region on the second stacked body including a region directly above the semiconductor pillar, and
the second interconnect is formed in a region on the second stacked body including a region directly above the first plug but not including a region directly above the second plug.
